(19) United States
(12) Patent Application Publication
(10) Pub. No.: US 2026/0040455 A1
(43) Pub. Date: Feb. 5, 2026

(54) CIRCUIT BOARD AND IMAGE FORMING APPARATUS

(71) Applicant: CANON KABUSHIKI KAISHA, Tokyo (JP)

(72) Inventor: KIYOKAZU UMIMURA, Chiba (JP)

(21) Appl. No.: 19/287,897

(22) Filed: Aug. 1, 2025

(30) Foreign Application Priority Data
Aug. 5, 2024 (JP) 2024-128943

(51) Int. Cl. H05K 1/18; H04N 1/40; H05K 1/14

(52) U.S. Cl. CPC H05K 1/18; H04N 1/40; H05K 1/142; H04N 2201/0094; H05K 2201/10022; H05K 2201/10151

(57) ABSTRACT

A circuit board includes a printed wiring board which includes a first mounting region on which a first component having a first terminal of a first function is mounted or mountable and a second mounting region on which a second component having a second terminal of the first function is mounted or mountable, one of the first component and the second component being exclusively mounted on the printed wiring board, and a peripheral circuit formed on the printed wiring board, wherein the peripheral circuit includes: a first node electrically connected to the first terminal, and a second node for electrically connected to the second terminal, and where the second node is a different node from the first node.

### BACKGROUND

### Field of the Technology

The present disclosure relates to a circuit board on which a semiconductor device that performs operation control is mounted, the circuit board being installed in an apparatus such as an image forming apparatus such as a printer, a copying machine, or a multifunction peripheral, and an image forming apparatus on which a semiconductor device is installed.

### Description of the Related Art

An image forming apparatus has installed thereon a circuit board on which a semiconductor device for controlling an operation of a built-in component is mounted. Examples of such a semiconductor device include a central processing unit (CPU), an application specific integrated circuit (ASIC), and a micro processing unit (MPU). The circuit board is typically configured by mounting a semiconductor device(s) on a printed wiring board. The printed wiring board is, for example, a board on which a conductive thin film is printed as wiring. In Japanese Patent Application Laid-open No. 2006-210735, there is disclosed a technology for exclusively mounting two types of semiconductor devices, which differ in package size, number of pins, pin arrangement, and the like, on a printed wiring board.

In the technology as disclosed in Japanese Patent Application Laid-open No. 2006-210735, functionally corresponding terminals between a plurality of semiconductor devices are connected to the same node. As long as characteristics of the plurality of semiconductor devices to be exclusively mounted are equivalent, the method as disclosed in Japanese Patent Application Laid-open No. 2006-210735 can be used to exclusively mount the plurality of semiconductor devices. However, in a case where electrical standards and characteristics are different between the plurality of semiconductor devices, even terminals having the same function may not produce predetermined output by being connected to the same node of the printed wiring board. Therefore, for the plurality of semiconductor devices having different characteristics, it is required to configure a printed wiring board in accordance with the characteristics of the respective semiconductor devices.

### SUMMARY

A circuit board according to some embodiments of the present disclosure includes a printed wiring board which includes a first mounting region on which a first component having a first terminal of a first function is mounted or mountable and a second mounting region on which a second component having a second terminal of the first function is mounted or mountable, one of the first component and the second component being exclusively mounted on the printed wiring board, and a peripheral circuit formed on the printed wiring board, wherein the peripheral circuit includes: a first node electrically connected to the first terminal, and a second node electrically connected to the second terminal, and wherein the second node is a different node from the first node.

An image forming apparatus according to another embodiment of the present disclosure includes an image forming unit configured to form an image, and a controller configured to control the image forming unit, wherein the controller includes a circuit board, wherein the circuit board includes a printed wiring board which includes a first mounting region on which a first component having a first terminal of a first function is mounted or mountable and a second mounting region on which a second component having a second terminal of the first function is mounted or mountable, one of the first component and the second component being exclusively mounted on the printed wiring board, and a peripheral circuit formed on the printed wiring board, wherein the peripheral circuit includes: a first node electrically connected to the first terminal, and a second node electrically connected to the second terminal, and wherein the second node is a different node from the first node.

Features of the present disclosure will become apparent from the following description of embodiments with reference to the attached drawings. The following description of embodiments is described by way of example.

### BRIEF DESCRIPTION OF THE DRAWINGS

FIG. 1 is a configuration diagram of an image forming system.

FIG. 2 is an explanatory diagram of a configuration of a controller.

FIG. 3 is an explanatory diagram of a configuration of a power supply control apparatus.

FIG. 4 is an explanatory diagram of a configuration of a circuit board of a voltage converter.

FIG. 5 is an explanatory diagram of a configuration of a circuit board of a voltage monitor.

FIG. 6 is an explanatory diagram of a configuration of a circuit board of a switch.

### DESCRIPTION OF THE EMBODIMENTS

Now, referring to the accompanying drawings, description is given of at least one exemplary embodiment of the present disclosure.

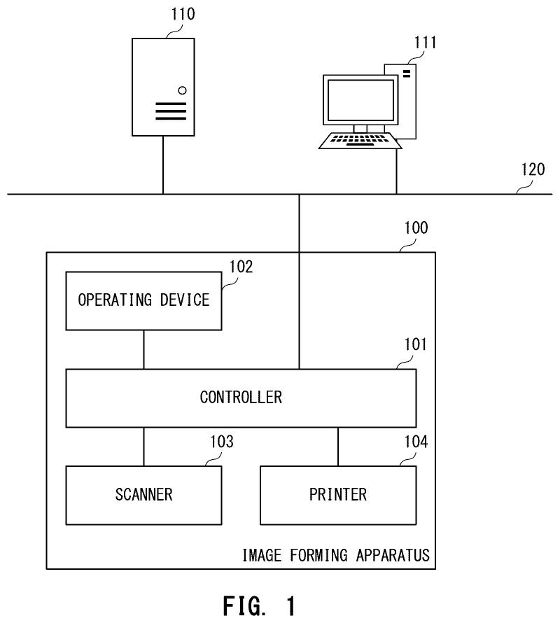

FIG. 1 is a configuration diagram of an image forming system including a circuit board according to the at least one embodiment. The image forming system includes an image forming apparatus 100, a client personal computer (PC) 110, and a print server 111. The image forming apparatus 100, the client PC 110, and the print server 111 are connected to each other through a network 120 so as to enable communication therebetween. The network 120 is a local area network (LAN), a wide area network (WAN), a public communication line, the Internet, or the like. A plurality of client PCs 110 may be provided on the network 120.

A user uses the client PC 110 to create a print job for printing, and instructs the image forming apparatus 100 to perform printing processing. The print job is input from the client PC 110 to the print server 111. The print server 111 transmits the print job acquired from the client PC 110 to the image forming apparatus 100. The image forming apparatus 100 performs predetermined image processing on image data representing an image to be formed on a sheet in accordance with the print job, and performs image forming processing (printing processing) on the sheet based on the image data subjected to the image processing.

The image forming apparatus 100 includes a controller 101, an operating device 102, a scanner 103, and a printer 104. The controller 101 is connected to each of the operating device 102, the scanner 103, and the printer 104, and controls an overall operation of the image forming apparatus 100. The controller 101 is also capable of communicating to/from the client PC 110 and the print server 111 through the network 120. Details of the controller 101 are described later.

The operating device 102 is a user interface including an input interface and an output interface. Examples of the input interface include various key buttons and a touch panel. Examples of the output interface include a display and a speaker. Instructions and data that are input through the input interface of the operating device 102 are transmitted to the controller 101. The output interface of the operating device 102 outputs, under the control of the controller 101, a status of the image forming apparatus 100, progress information on the printing processing, information for input, and the like.

The scanner 103 is an image reading apparatus that operates under the control of the controller 101 to read an image from an original. The scanner 103 transmits image data representing the image of the original to the controller 101 as a result of reading the image from the original.

The printer 104 operates under the control of the controller 101 to print an image based on the image data onto a sheet. The printer 104 forms an image by a general-purpose method such as an electrophotographic method or an inkjet method. The controller 101 controls the printing processing performed by the printer 104 based on the image data acquired from the client PC 110 or the scanner 103.

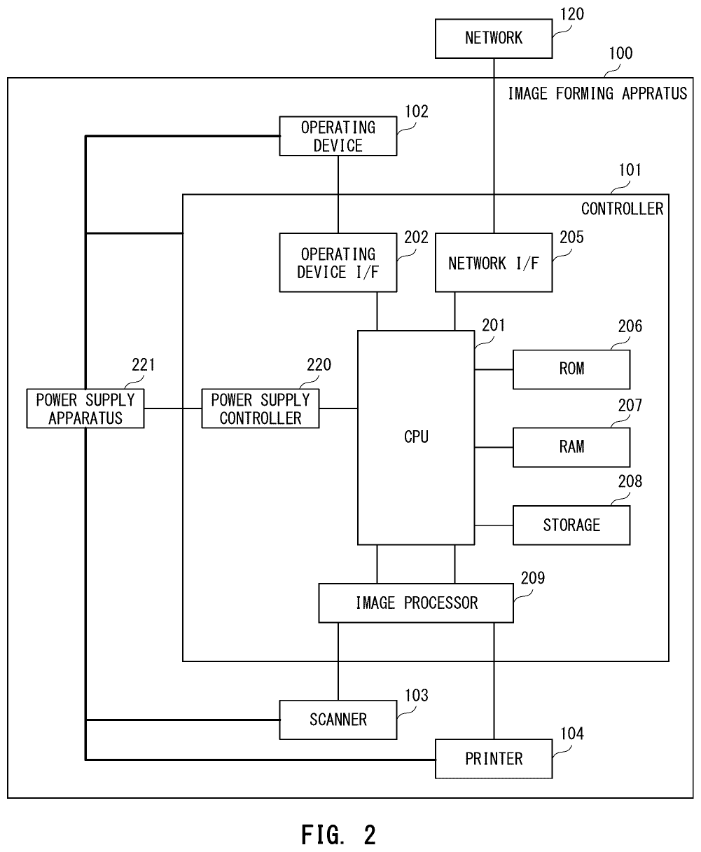

FIG. 2 is an explanatory diagram of a configuration of the controller 101. The controller 101 is an information processing apparatus including a CPU 201, a read only memory (ROM) 206, and a random access memory (RAM) 207. The controller 101 includes an operating device I/F 202, a network I/F 205, a storage 208, a power supply controller 220 for power supply control, and an image processor 209 for the image processing. The ROM 206, the RAM 207, the operating device I/F 202, the network I/F 205, the storage 208, the image processor 209, and the power supply controller 220 are connected to the CPU 201. The controller 101, the operating device 102, the scanner 103, and the printer 104 are supplied with electric power for operations thereof from a power supply apparatus 221.

The CPU 201 can communicate with (to/from) the operating device 102 through an operating device I/F 202. The operating device I/F 202 is connected to the operating device 102, and performs interface control between the operating device 102 and the CPU 201. The CPU 201 can also communicate to/from the client PC 110 and the print server 111 through the network I/F 205. The network I/F 205 is connected to the network 120, and performs interface control between the client PC 110 and print server 111 and the CPU 201 through the network 120. The network I/F 205 allows input and output of the image data, device information, and the like to/from external apparatus (such as the client PC 110 and the print server 111) through the network 120.

The CPU 201 is a main controller that controls the operation of the image forming apparatus 100 by executing a computer program stored in at least one of the ROM 206 and the storage 208. For example, the CPU 201 executes a startup program stored in the ROM 206 and required for system startup, and executes a control program stored in the storage 208 after startup, to thereby control the overall operation of the image forming apparatus 100. The ROM 206 is a boot ROM. The storage 208 is a non-volatile large-capacity storage device such as a solid state drive (SSD) or a hard disk drive (HDD). In addition to control programs such as an operating system and application programs, the storage 208 stores setting values and user data that are required to be held even after the image forming apparatus 100 is shut down. The RAM 207 is a main memory to be used in a case where the CPU 201 executes a computer program, and provides a work area in which temporary data storage or the like is performed.

The image processor 209 performs, in response to an instruction received from the CPU 201, predetermined image processing such as correction, modification, or editing on the image data acquired from the print server 111 through the network 120 or the image data acquired from the scanner 103. The image processor 209 also performs, in response to an instruction received from the CPU 201, image processing such as color conversion, filter processing, or resolution conversion processing on the image data to generate image data suitable for the printing processing to be performed by the printer 104.

For example, when performing copy processing, the CPU 201 causes the scanner 103 to read an image of an original to acquire image data. The CPU 201 causes the image processor 209 to perform the image processing on the acquired image data, and causes the printer 104 to perform the printing processing through use of the image data subjected to the image processing. The printer 104 performs the printing processing in accordance with an instruction received from the CPU 201, to thereby print an image similar to the image of the original on a sheet.

The power supply controller 220 is connected to the power supply apparatus 221, and controls power supply performed by the power supply apparatus 221. The power supply apparatus 221 generates DC power (operating voltages) required for internal operations of the image forming apparatus 100 based on AC power supplied from a commercial power source, and supplies the DC power to the controller 101, the operating device 102, the scanner 103, and the printer 104. The operating voltages to be supplied to the controller 101, the operating device 102, the scanner 103, and the printer 104 have voltage values suitable for the operations of the respective devices. For that reason, the power supply apparatus 221 serves as power supply equipment that can generate operating voltages having a plurality of different voltage values.

The power supply controller 220 controls the power supply by transmitting a control signal to the power supply apparatus 221 based on an instruction acquired from the CPU 201. The power supply apparatus 221 supplies DC power to the respective devices of the image forming apparatus 100 based on the control signal acquired from the power supply controller 220. The power supply apparatus 221 is constantly energized to be able to supply electric power as long as the power supply apparatus 221 is connected to the commercial power source through a power cable. The power supply apparatus 221 includes a first power supply module and a second power supply module which are described later.

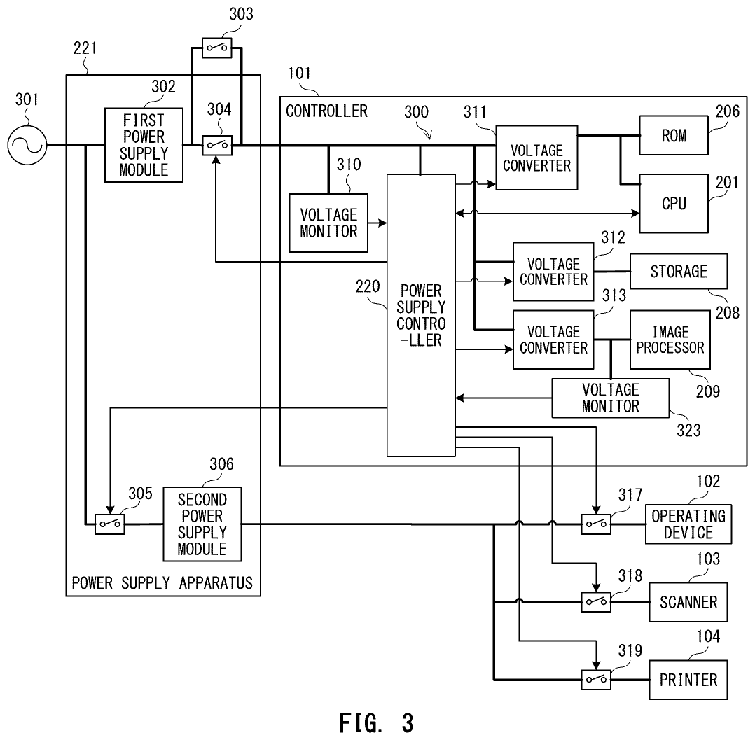

FIG. 3 is an explanatory diagram of a configuration of a power supply control apparatus included in the image forming apparatus 100. A power supply control apparatus 300 in the at least one embodiment is provided in the controller 101. The power supply control apparatus 300 includes, for example, the power supply controller 220, voltage monitors 310 and 323, and voltage converters 311, 312, and 313.

The voltage monitor 310 monitors the voltage value of electric power being supplied from the power supply apparatus 221, and transmits a monitoring result thereof to the power supply controller 220. The power supply controller 220 controls the supply of electric power based on the monitoring result acquired from the voltage monitor 310. The voltage converter 311 converts the voltage value of the electric power supplied from the power supply apparatus 221 into a voltage value suitable for an operation of each of the ROM 206 and the CPU 201, and supplies the voltage value to each of the ROM 206 and the CPU 201. The voltage converter 312 converts the voltage value of the electric power supplied from the power supply apparatus 221 into a voltage value suitable for an operation of the storage 208, and supplies the voltage value to the storage 208. The voltage converter 313 converts the voltage value of the electric power supplied from the power supply apparatus 221 into a voltage value suitable for an operation of the image processor 209, and supplies the voltage value to the image processor 209. The voltage monitor 323 monitors the voltage value of electric power being supplied from the voltage converter 313 to the image processor 209, and transmits a monitoring result thereof to the power supply controller 220.

The power supply controller 220 controls an operation of the power supply apparatus 221. The power supply controller 220 controls opening and closing of a switch 317 provided on a line for supplying electric power from the power supply apparatus 221 to the operating device 102. The power supply controller 220 controls opening and closing of a switch 318 provided on a line for supplying electric power from the power supply apparatus 221 to the scanner 103. The power supply controller 220 controls opening and closing of a switch 319 provided on a line for supplying electric power from the power supply apparatus 221 to the printer 104. The power supply controller 220 can individually control the power supply to the operating device 102, the scanner 103, and the printer 104 by controlling the opening and closing of the switches 317, 318, and 319.

The power supply apparatus 221 includes a first power supply module 302 and a second power supply module 306, and a main power switch 303 is connected to the power supply apparatus 221. Through an operation of the main power switch 303, the power supply apparatus 221 controls supply and stop of electric power, to thereby be able to start up or shut down the image forming apparatus 100.

A switch 304 is provided on a path for supplying electric power from the first power supply module 302 to the controller 101. The main power switch 303 is connected in parallel to the switch 304. A switch 305 is provided on a path for supplying electric power from a commercial power source 301 to the second power supply module 306. The power supply controller 220 controls opening and closing of the switches 304 and 305. The power supply controller 220 can control the power supply to the controller 101 by controlling the opening and closing of the switch 304. The power supply controller 220 can control the power supply to the second power supply module 306 by controlling the opening and closing of the switch 305.

The first power supply module 302 and the second power supply module 306 each generate DC power to be used by the respective devices in the image forming apparatus 100 from AC power supplied from the commercial power source 301. The first power supply module 302 generates DC power to be supplied to the power supply controller 220 and the voltage converters 311, 312, and 313 based on the AC power supplied from the commercial power source 301. The second power supply module 306 generates DC power to be supplied to the operating device 102, the scanner 103, and the printer 104 based on the AC power supplied from the commercial power source 301. The DC power generated by the first power supply module 302 and the DC power generated by the second power supply module 306 may have the same value, or may have different values.

The image forming apparatus 100 can operate in at least two operating states: a standby state in which functions for image reading by the scanner 103, printing by the printer 104, and the like can be used; and a power saving state in which the image forming apparatus 100 is on standby and is consuming less electric power than in the standby state. The first power supply module 302 always supplies electric power in both the standby state and the power saving state irrespective of the operating state. The second power supply module 306 has the switch 305 controlled by the power supply controller 220 depending on the operating state. The second power supply module 306 supplies electric power in the standby state, and stops supplying electric power in the power saving state.

Power control to be performed to start up the image forming apparatus 100 is described. The startup causes electric power to be supplied to the respective devices of the image forming apparatus 100.

The user operates the main power switch 303 to a closed state. The main power switch 303 is, for example, a rocker switch. In a case where the main power switch 303 is brought into a closed state, the DC power generated by the first power supply module 302 is supplied to the power supply controller 220 of the controller 101. The voltage monitor 310 monitors whether or not the voltage value of a line for supplying electric power from the first power supply module 302 to the power supply controller 220 has exceeded a predetermined threshold value. In a case where the voltage monitor 310 detects that the voltage value has exceeded the predetermined threshold value, the voltage monitor 310 notifies the power supply controller 220 of a power good signal as a monitoring result.

In a case where the power supply controller 220 acquires the power good signal from the voltage monitor 310, the power supply controller 220 activates the voltage converters 311, 312, and 313, and controls the switches 317, 318, and 319 to be in a closed state. The voltage converters 311, 312, and 313 convert, by being activated, a voltage supplied from the first power supply module 302 in accordance with voltage values of the operating voltages for the CPU 201 and ROM 206, the storage 208, and the image processor 209 which are connected downstream of the voltage converters 311, 312, and 313, respectively. The voltage converters 311, 312, and 313 supply the converted voltages to the CPU 201 and ROM 206, the storage 208, and the image processor 209, respectively.

The voltage monitor 323 monitors whether or not a voltage being supplied from the voltage converter 313 to the image processor 209 is within a range of the operating voltage for the image processor 209. In a case where the voltage being supplied from the voltage converter 313 to the image processor 209 is within the range of the operating voltage for the image processor 209, the voltage monitor 323 transmits a power good signal to the power supply controller 220. In a case where the power supply controller 220 acquires the power good signal from the voltage monitor 323, the power supply controller 220 transmits a processing start instruction to the CPU 201. In a case where the CPU 201 acquires the processing start instruction from the power supply controller 220, the CPU 201 executes startup processing in accordance with the startup program stored in the ROM 206. The startup processing causes the operating state of the image forming apparatus 100 to transition to the standby state.

After having been started up, the image forming apparatus 100 can operate in the standby state and the power saving state as described above.

In the standby state, the power supply apparatus 221 supplies electric power to the respective devices, namely, the controller 101, the operating device 102, the scanner 103, and the printer 104. In a case where the operating state shifts to the standby state, or in a case where the operating state shifts to the power saving state, the CPU 201 transmits a control signal to rewrite the register value in the power supply controller 220. The power supply controller 220 controls, based on the rewritten register value, the voltage converters 311, 312, and 313 and the switches 304, 305, 317, 318, and 319 to control the power supply to the respective devices. In this case, the switches 304, 305, 317, 318, and 319 are all controlled to be in a closed state. In a case where the electric power is supplied in this manner, the user can use, in the standby state, functions such as scanning and printing of the image forming apparatus 100.

In the power saving state, the power supply apparatus 221 supplies electric power to the power supply controller 220. The CPU 201 controls the power supply controller 220 so as to enable the power supply to a part of the controller 101 and disable the power supply to the operating device 102, the scanner 103, and the printer 104. In the power saving state, the power supply controller 220 stops the voltage converters 312 and 313, and brings the switches 317, 318, and 319 into an open state, to thereby stop the power supply to the part of the controller 101 and the operating device 102, the scanner 103, and the printer 104. After that, the power supply controller 220 brings the switch 305 into an open state to stop the second power supply module 306, to thereby reduce standby power of the second power supply module 306.

In a case where the power supply controller 220 detects, for example, an operation performed on the operating device 102 by the user or reception of data from an external apparatus through the network 120, the operating state of the image forming apparatus 100 shifts from the power saving state to the standby state.

Power control to be performed to shut down the image forming apparatus 100 is described. The shutdown causes the power supply to the respective devices of the image forming apparatus 100 to be cut off.

The user operates the main power switch 303 to an open state. In a case where the operating state is the standby state or the power saving state, the switch 304 is in a closed state, and hence even when the main power switch 303 is brought into an open state, the power supply to the controller 101 is not immediately cut off. During that time, the CPU 201 detects that the main power switch 303 has been operated to an open state, and performs control to shut down the image forming apparatus 100.

To that end, the CPU 201 ends the application programs, and saves setting values, user data, and the like to the storage 208. After that, the CPU 201 controls the power supply controller 220 to cut off the power supply to the controller 101, the operating device 102, the scanner 103, and the printer 104. The power supply controller 220 stops the voltage converters 311, 312, and 313, and brings the switches 304, 305, 317, 318, and 319 into an open state, to thereby stop the power supply to the respective devices.

The controller 101 as described above may be configured as a circuit board in which respective components are mounted on a board. In another embodiment, the power supply controller 220, the voltage monitors 310 and 323, the voltage converters 311, 312, and 313, and the switches 304, 305, 317, 318, and 319 in the controller 101 may each be configured as a circuit board in which electronic components are mounted on a board. As the board, for example, a printed wiring board on which a conductive thin film is printed as wiring is used. The electronic components on the printed wiring board are connected by the conductive thin film to configure a circuit.

A plurality of semiconductor devices having different characteristics may be exclusively mounted on the printed wiring board. For example, in order to continue manufacturing the circuit board even when a procurement problem occurs, in addition to regular components, alternative components having functions equivalent to those of the regular components may be selected. Further, when manufacturing a plurality of apparatus having different specifications depending on needs of users, semiconductor devices having different characteristics may be mounted on the same printed wiring board. In another case, in order to upgrade the apparatus, an existing semiconductor device may be replaced by a new semiconductor device having a different characteristic. In the at least one embodiment, peripheral components are mounted and wired in advance so that the apparatus operates normally even when any one of the plurality of semiconductor devices having different characteristics is mounted. A peripheral circuit is configured by a plurality of peripheral components. For the sake of convenience, the peripheral components include peripheral components for a first semiconductor device, peripheral components for a second semiconductor device, and peripheral components shared by the first and second semiconductor devices. Configurations of the respective circuit boards of a voltage converter, a voltage monitor, and a switch are described below.

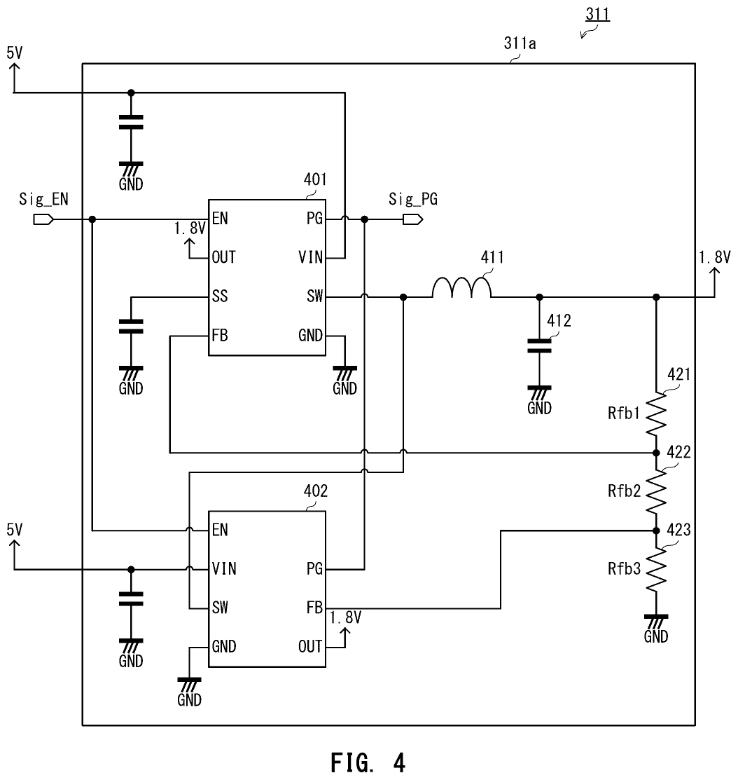

FIG. 4 is an explanatory diagram of a configuration of the circuit board of the voltage converters 311, 312, and 313. Herein, the voltage converter 311 is described as an example, but the voltage converters 311, 312, and 313 have the same circuit configuration itself except that only voltage values to be output therefrom are different. The respective electronic components of the voltage converter 311 are mounted on a printed wiring board 311a.

In the voltage converter 311, a DC-DC converter 401 and a DC-DC converter 402 which differ in type are exclusively mounted. Both the DC-DC converters 401 and 402 are semiconductor devices. The DC-DC converter 401 and the DC-DC converter 402 are exclusively mounted in different mounting regions (first mounting region and second mounting region) provided in different regions of the printed wiring board 311a. The DC-DC converters 401 and 402 are provided with terminals including an input terminal VIN, an output terminal SW, a ground (GND) terminal, and a feedback terminal FB.

DC power is supplied to the input terminal VIN from the power supply apparatus 221. In this case, DC power having a voltage value of 5 V is input to the input terminal VIN. A smoothing circuit configured by a shared inductor 411 and a smoothing capacitor 412 is connected to the output terminal SW. A pulse signal output from the output terminal SW is smoothed by the smoothing circuit to be output as a DC output voltage of 1.8 V. Feedback resistors 421, 422, and 423 are connected to the feedback terminal FB. The feedback resistors 421, 422, and 423 are connected in series, and are resistor elements configuring a peripheral circuit that divides the output voltage. A divided voltage value of the output voltage obtained by the feedback resistors 421, 422, and 423, and the divided voltage value is input to the feedback terminal FB.

Mutually different reference voltage values are set for the DC-DC converter 401 and the DC-DC converter 402. The reference voltage value is a voltage value for determining the output voltage. For example, a reference voltage value of 0.8 V is set for the DC-DC converter 401, and a reference voltage value of 0.6 V is set for the DC-DC converter 402. The output voltage is set by the reference voltage value and resistance values of the feedback resistors 421, 422, and 423. Output voltages Vout are set by the following equations. Equation 1 is an equation for setting the output voltage Vout of the DC-DC converter 401. Equation 2 is an equation for setting the output voltage Vout of the DC-DC converter 402.

$$V out = \{ ( Rfb 1 + Rfb 2 + Rfb 3 ) / ( Rfb 2 + Rfb 3 ) \} \times 0.8 \qquad ( Equation 1 )$$

$$V out = \{ ( Rfb 1 + Rfb 2 + Rfb 3 ) / ( Rfb 3 ) \} \times 0.6 \qquad ( Equation 2 )$$

An example of resistance values of the feedback resistors 421, 422, and 423 when setting the output voltage of the voltage converter 311 to 1.8 V is described. In a case where the resistance value of the feedback resistor 421 is set to 100 kΩ, the resistance value of the feedback resistor 422 is set to 20 kΩ, and the resistance value of the feedback resistor 423 is set to 60 kΩ, the output voltage is set to 1.8 V irrespective of which one of the DC-DC converters 401 and 402 is used.

The output voltage Vout (divided voltage value) divided by the feedback resistors 421, 422, and 423 is input to the feedback terminal FB. However, the divided voltage value between the feedback resistor 421 and the feedback resistor 422 is input to the feedback terminal FB of the DC-DC converter 401. The divided voltage value between the feedback resistor 422 and the feedback resistor 423 is input to the feedback terminal FB of the DC-DC converter 402. That is, the feedback terminal FB of the DC-DC converter 401 and the feedback terminal FB of the DC-DC converter 402 are connected to mutually different nodes. Specifically, the feedback terminal FB of the DC-DC converter 401 and the feedback terminal FB of the DC-DC converter 402 in the at least one embodiment are connected to different nodes of a voltage divider configured by the feedback resistors 421, 422, and 423.

Each of the DC-DC converters 401 and 402 controls the output voltage based on the divided voltage value input to the feedback terminal FB. That is, the output voltage Vout is fed back to the input side through the feedback terminal FB for self-control. In this manner, the feedback terminal FB of the DC-DC converter 401 and the feedback terminal FB of the DC-DC converter 402 have the same function, specifically, the function of feeding back the output voltage to the input side. Meanwhile, the DC-DC converter 401 and the DC-DC converter 402 have different characteristics. Therefore, in a case where the output voltage Vout having the same value (in this case, 1.8 V) is output from both, different divided voltage values are input to the DC-DC converter 401 and the DC-DC converter 402. In view of this, in the at least one embodiment, the feedback terminal FB of the DC-DC converter 401 and the feedback terminal FB of the DC-DC converter 402 are connected to different nodes, and hence a common printed board can be used irrespective of which component is mounted.

Other terminals provided to the DC-DC converters 401 and 402 include an enable terminal EN, an OUT terminal, and a power good terminal PG. The DC-DC converter 401 further includes a soft start terminal SS. An enable signal for controlling the output of the output voltage Vout is input to the enable terminal EN from the power supply controller 220. In a case where the enable signal is valid, the output voltage Vout is output, and in a case where the enable signal is invalid, the output voltage Vout is not output. An external capacitor is connected to the soft start terminal SS, and the soft start terminal SS is used to adjust a time period after the enable signal becomes valid until the output voltage Vout reaches a predetermined voltage value. In a case of including no soft start terminal SS as in the case of the DC-DC converter 402, a time period until the output voltage Vout reaches the predetermined voltage value assumes a fixed value such as 1 millisecond. The OUT terminal is used by the DC-DC converters 401 and 402 to detect the voltage value of the output voltage Vout. For example, the output voltage Vout is transmitted from the OUT terminal to the power supply controller 220, and the voltage value of the output voltage is detected by the power supply controller 220. The power good terminal PG is used to output a power good signal for notifying the power supply controller 220 that the output voltage Vout has reached the predetermined voltage value. The notification of the power good signal is used to control a rising order of the output voltage Vout and a timing of releasing reset of the CPU 201.

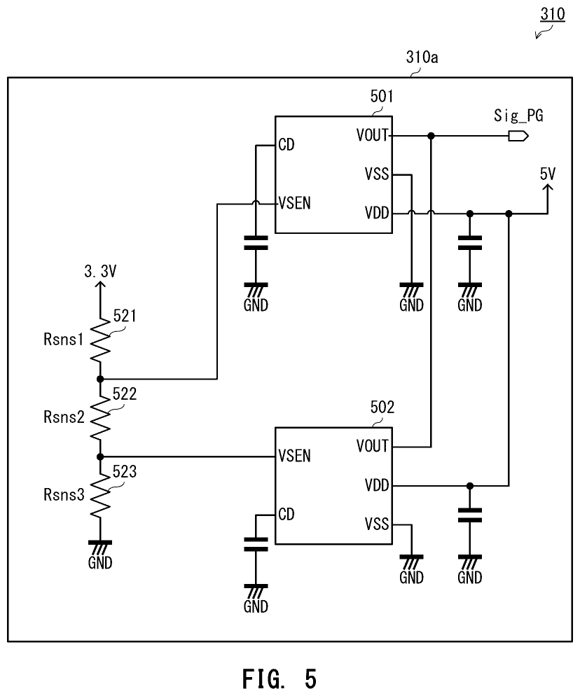

FIG. 5 is an explanatory diagram of a configuration of the circuit board of the voltage monitors 310 and 323. Herein, the voltage monitor 310 is described as an example, but the voltage monitors 310 and 323 have the same circuit configuration itself except that only voltage values to be monitored are different. The respective electronic components of the voltage monitor 310 are mounted on a printed wiring board 310a.

The voltage monitor 310 includes a reset integrated circuit (IC). In FIG. 5, in the voltage monitor 310, a reset IC 501 and a reset IC 502 which differ in type are exclusively mounted. Both the reset ICs 501 and 502 are semiconductor devices. The reset IC 501 and the reset IC 502 have mutually different characteristics. The reset ICs 501 and 502 are provided with terminals including a power supply terminal VDD, a GND terminal VSS, a sense terminal VSEN, and an output terminal VOUT.

A power supply voltage to be monitored is input to the power supply terminal VDD. In this case, a power supply voltage of 5 V is applied from the power supply terminal VDD. Sense resistors 521, 522, and 523 are connected to the sense terminal VSEN. The sense resistors 521, 522, and 523 are connected in series, and are resistor elements configuring a peripheral circuit that divides the power supply voltage. A divided voltage value of the power supply voltage obtained by the sense resistors 521, 522, and 523 is input to the sense terminal VSEN. The divided voltage value between the sense resistor 521 and the sense resistor 522 is input to the sense terminal VSEN of the reset IC 501. A divided voltage value between the sense resistor 522 and the sense resistor 523 is input to the sense terminal VSEN of the reset IC 502. That is, the reset ICs 501 and 502 are respectively connected to different nodes of a voltage divider configured by the sense resistors 521, 522, and 523. Different detection voltage values are set to the respective reset ICs 501 and 502. For example, the reset IC 501 is set to a detection voltage value of 1.0 V, and the reset IC 502 is set to a detection voltage value of 0.8 V.

The voltage value to be monitored is set by the detection voltage value and the resistance values of the sense resistors 521, 522, and 523. Setting values of the voltage value to be monitored are determined by the following equations. Equation 3 is an equation for setting the setting value of the voltage value to be monitored of the reset IC 501. Equation 4 is an equation for setting the setting value of the voltage value to be monitored of the reset IC 502.

$$V DET = \{ ( Rsns 1 + Rsns 2 + Rsns 3 ) / ( Rsns 2 + Rsns 3 ) \} \times 1. \qquad ( Equation 3 )$$

$$V DET = \{ ( Rsns 1 + Rsns 2 + Rsns 3 ) / ( Rsns 3 ) \} \times 0.8 \qquad ( Equation 4 )$$

An example of resistance values of the sense resistors 521, 522, and 523 when setting the voltage value to be monitored to 3.0 V is described. In a case where the resistance value of the sense resistor 521 is set to 100 kΩ, the resistance value of the sense resistor 522 is set to 10 kΩ, and the resistance value of the sense resistor 523 is set to 40 kΩ, the voltage value to be monitored is set to 3.0 V irrespective of which one of the reset ICs 501 and 502 is used. The detection voltage value and the input divided voltage value are different, and hence the voltage value to be monitored can be set to 3.0 V irrespective of the difference in characteristics of the reset ICs 501 and 502.

The output terminal VOUT is used to output a power good signal for notifying that the voltage being monitored by the sense terminal VSEN has reached a predetermined voltage value. The notification of the power good signal is used to control the rising order of the output voltage and the timing of releasing the reset of the CPU 201.

As another terminal provided to the reset ICs 501 and 502, there is a delay terminal CD. An external capacitor is connected to the delay terminal CD. The delay terminal CD is used to adjust a time period after the voltage being monitored by the sense terminal VSEN has reached a predetermined value until the output terminal VOUT switches the power good signal. A delay function is used to control timings from application of the power supply voltage to the release of the reset of the CPU 201.

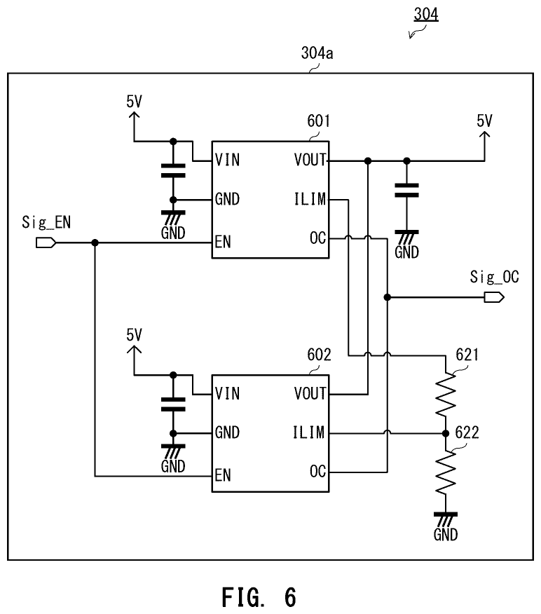

FIG. 6 is an explanatory diagram of a configuration of the circuit board of the switches 304, 305, 317, 318, and 319. Herein, the switch 304 is described as an example, but the switches 304, 305, 317, 318, and 319 have the same circuit configuration itself. The respective electronic components of the switch 304 is mounted on a printed wiring board 304a.

In the switch 304, a load switch IC 601 and a load switch IC 602 which differ in type are exclusively mounted. The load switch ICs 601 and 602 are both semiconductor devices. The load switch IC 601 and the load switch IC 602 have mutually different characteristics. The load switch ICs 601 and 602 are provided with terminals including an input terminal VIN, an output terminal VOUT, a GND terminal, an enable terminal EN, an overcurrent detection value setting terminal ILIM, and an overcurrent notification terminal OC.

DC power is supplied to the input terminal VIN from the first power supply module 302. In this case, DC power having a voltage value of 5 V is input to the input terminal VIN. The output terminal VOUT outputs a power supply voltage (DC power) of 5 V being input to the input terminal VIN in accordance with an enable signal Sig_EN input to the enable terminal EN. An enable signal Sig_EN (control signal) for controlling the output of the output voltage from the output terminal VOUT is input to the enable terminal EN from the power supply controller 220. In a case where the enable signal Sig_EN is valid, the output voltage is output, and in a case where the enable signal Sig_EN is invalid, the output voltage is not output.

External resistors (resistor 621 and resistor 622) are connected to the overcurrent detection value setting terminal ILIM. The resistors 621 and 622 are resistor elements connected in series to configure a peripheral circuit. The overcurrent detection value setting terminal ILIM of the load switch IC 601 is grounded through the resistor 621 and the resistor 622. The overcurrent detection value setting terminal ILIM of the load switch IC 602 is grounded through the resistor 622. An upper limit value (overcurrent detection value) of an amount of each of currents flowing through the load switch ICs 601 and 602 is set by the resistors 621 and 622. Resistance values to be exhibited by the resistors 621 and 622 are required to be set to different resistance values between those for the load switch IC 601 and the load switch IC 602. For that reason, the overcurrent detection value setting terminals ILIM of the load switch ICs 601 and 602 are connected to different nodes of the external resistors.

For example, when setting the overcurrent detection value to 1.5 A, a combined resistance value of the resistors 621 and 622 is set to, for example, 36 kΩ for the load switch IC 601 and 13 kΩ for the load switch IC 602. To that end, the resistance value of the resistor 621 is set to 23 kΩ, and the resistance value of the resistor 622 is set to 13 kΩ. Therefore, an external resistance value of the external resistor connected to the overcurrent detection value setting terminal ILIM of the load switch IC 601 is set to 36 kΩ. An external resistance value of the external resistor connected to the overcurrent detection value setting terminal ILIM of the load switch IC 602 is set to 13 kΩ.

In this manner, the overcurrent detection value setting terminals ILIM are connected to different nodes of the external resistors, to thereby enable the overcurrent detection value to be set to a predetermined current value (in this case, 1.5 A) irrespective of the difference in the characteristics of the load switch ICs 601 and 602. A notification signal Sig_OC is output from the overcurrent notification terminal OC in a case where the set overcurrent detection value is exceeded. The notification signal Sig_OC is transmitted from the overcurrent notification terminal OC to the CPU 201. The notification signal Sig_OC enables the CPU 201 to detect that an amount of each of currents flowing through the load switch ICs 601 and 602 has exceeded a setting value (overcurrent detection value).

As described above, the circuit boards (of the voltage converter, the voltage monitor, the switch, and the like) installed on the image forming apparatus 100 each have a printed wiring board on which a plurality of semiconductor devices having mutually different characteristics are exclusively mounted. In order to compensate for the difference in characteristics, terminals to which signals (voltage values) to be used for the functions are input are connected to different nodes of a peripheral circuit. The difference in characteristics is compensated for in accordance with the connected nodes of the peripheral circuit. Therefore, even the plurality of semiconductor devices having mutually different characteristics can be exclusively mounted by being simply replaced without changing configurations of other peripheral components.

The different nodes (a configuration where a first node and a second node are different from each other) are not limited to the above-mentioned examples. For example, the two different nodes may be any two nodes with a circuit element being arranged on an electrical path therebetween. From another viewpoint, two nodes that are at different voltages in a case where electric power is being applied to the peripheral circuit can be said to be the above-mentioned two different nodes. Further, two electrically insulated nodes can be the two different nodes. All those conditions are not required to be satisfied at the same time. For example, even when two electrically insulated nodes have the same voltage value, the two electrically insulated nodes can be the two different nodes due to the electrical insulation.

As described above, according to the present disclosure, a plurality of semiconductor devices having different characteristics can be exclusively mounted on one board.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-128943, filed Aug. 5, 2024, which is hereby incorporated by reference herein in its entirety.

What is claimed is:

1. A circuit board comprising:
a printed wiring board which includes a first mounting region on which a first component having a first terminal of a first function is mounted or mountable and a second mounting region on which a second component having a second terminal of the first function is mounted or mountable, one of the first component and the second component being exclusively mounted on the printed wiring board; and
a peripheral circuit formed on the printed wiring board,
wherein the peripheral circuit includes
a first node electrically connected to the first terminal, and
a second node electrically connected to the second terminal, and
wherein the second node is a different node from the first node.

2. The circuit board according to claim 1, wherein the first node and the second node have therebetween an electrical path on which a circuit element is arranged.

3. The circuit board according to claim 1, wherein the first node and the second node have different voltages in a case where electric power is being applied to the peripheral circuit.

4. The circuit board according to claim 1, wherein the first node and the second node are electrically insulated.

5. The circuit board according to claim 1,
wherein the peripheral circuit includes a first resistor element, a second resistor element, and a third resistor element which are connected in series,
wherein the first node is a node between the first resistor element and the second resistor element, and
wherein the second node is a node between the second resistor element and the third resistor element.

6. The circuit board according to claim 5,
wherein the first component and the second component are each a semiconductor device configured to convert and output a voltage value of an input voltage, and
wherein the voltage output from the semiconductor device is divided by the first resistor element, the second resistor element, and the third resistor element, and the divided voltage is input to one of the first terminal and the second terminal.

7. The circuit board according to claim 6, wherein the semiconductor device is configured to control, based on the divided voltage, a voltage value of a voltage to be output.

8. The circuit board according to claim 5,
wherein the first component and the second component are each a semiconductor device configured to monitor a voltage value of an input voltage, and
wherein the first resistor element, the second resistor element, and the third resistor element are configured to divide a voltage value to be monitored.

9. The circuit board according to claim 1,
wherein the peripheral circuit includes a first resistor element and a second resistor element which are connected in series,
wherein the first terminal of the first component is, in a case of being mounted, connected to the first resistor element, and
wherein the second terminal of the second component is, in a case of being mounted, connected to a node between the first resistor element and the second resistor element.

10. An image forming apparatus comprising:
an image forming unit configured to form an image; and
a controller configured to control the image forming unit,
wherein the controller includes a circuit board,
wherein the circuit board includes
a printed wiring board which includes a first mounting region on which a first component having a first terminal of a first function is mounted or mountable and a second mounting region on which a second component having a second terminal of the first function is mounted or mountable, one of the first component and the second component being exclusively mounted on the printed wiring board, and
a peripheral circuit formed on the printed wiring board,
wherein the peripheral circuit includes
a first node electrically connected to the first terminal; and
a second node electrically connected to the second terminal, and
wherein the second node is a different node from the first node.
